(19) United States
(12) Patent Application Publication
(10) Pub. No.: US 2023/0244140 A1
(43) Pub. Date: Aug. 3, 2023

(54) PHOTOSENSITIVE RESIN COMPOSITION, AND PHOTOSENSITIVE RESIN FILM AND COLOR FILTER MANUFACTURED BY USING SAME

(71) Applicant: SAMSUNG SDI CO., LTD., Yongin-si, Gyeonggi-do (KR)

(72) Inventors: Ieju KIM, Suwon-si, Gyeonggi-do (KR); Seungbeom KEE, Suwon-si, Gyeonggi-do (KR); Juho JUNG, Suwon-si, Gyeonggi-do (KR)

(21) Appl. No.: 17/919,025

(22) PCT Filed: Mar. 11, 2021
(86) PCT No.: PCT/KR2021/002996

§ 371 Date: Oct. 14, 2022

(30) Foreign Application Priority Data
Apr. 16, 2020 (KR) 10-2020-0046181

(51) Int. Cl. G03F 7/00; G03F 7/033; G03F 7/004; C09D 5/32; C09D 4/06; C09D 135/02; C09D 7/63; C09D 7/41

(52) U.S. Cl. CPC G03F 7/0007; C09D 4/06; C09D 5/32; C09D 7/41; C09D 7/63; C09D 135/02; G03F 7/033; G03F 7/0045

(57) ABSTRACT

Provided are a photosensitive resin composition, a photosensitive resin film manufactured by using the photosensitive resin composition, and a color filter including same, the photosensitive resin composition including: (A) a binder resin; (B) a colorant; (C) a polymerizable compound; (D) an initiator comprising a photopolymerization initiator and a thermal polymerization initiator; and (E) a solvent, wherein the thermal polymerization initiator has a half-life of 50 or less (t½ = 10 h), and the thermal polymerization initiator is included in an amount equal to or greater than that of the photopolymerization initiator.

### TECHNICAL FIELD

This disclosure relates to a photosensitive resin composition, and a photosensitive resin film and a color filter manufactured by using same.

### BACKGROUND ART

A liquid crystal display (LCD) among many types of displays has an advantage of lightness, thinness, low cost, low power consumption for operation, and improved adherence to an integrated circuit and has been more widely used for a laptop computer, a monitor, and a TV screen. This liquid crystal display (LCD) is equipped with a color filter formed by repeating a unit pixel, in which three primary color sub-pixels of red (R), green (G), and blue (B) are combined. When the brightness is controlled by applying a color signal to each sub-pixel in a state in which each sub-pixel is arranged adjacently, a specific color is displayed in the unit pixel due to a combination of three primary colors. The color filter is made of red (R), green (G), and blue (B) dyes or pigments, and this colorant serves to change the white light of the backlight unit into the corresponding color. The color purity is improved as a spectrum of the colorant has a narrow absorption band without unnecessary wavelengths other than the required absorption wavelength. In addition, the color materials are required to have excellent heat resistance, light resistance, and chemical resistance without being faded or discolored under a condition of ultraviolet (UV), acid, and base to which exposed during the etching of a color resist. A color filter using the photosensitive resin composition may be manufactured by coating three or more colors on a transparent substrate mainly by a dyeing method, an electrodeposition method, a printing method, a pigment dispersion method, or the like.

In addition to this LCD process, attempts to adopt a next generation display process based on dye or pigment technology for the photosensitive resin composition have been rapidly increasing in recent years.

The conventional LCD process is designed for securing durability in a high-temperature process, but since the next generation display process requires a low-temperature process to minimize a heat deformation loss due to material properties of thin films, and in addition, an organic light emitting diode (OLED) due to material properties requires the low-temperature process, a photosensitive resin composition used therein should have excellent low-temperature curing properties, but a photosensitive resin composition used in the conventional LCD process exhibits only excellent high-temperature curing properties but very inferior low-temperature curing properties. Accordingly, in recent years, there is a very high need for a low-temperature curable resin composition. However, most of low-temperature curable resin compositions known to date are not sufficiently cured during the low-temperature curing and thus have a problem of weak heat resistance and chemical resistance.

### DISCLOSURE

### Technical Problem

An embodiment provides a photosensitive resin composition having excellent curing characteristics at a low temperature, for example, 80° C. to 100° C.

Another embodiment provides a photosensitive resin film manufactured using the photosensitive resin composition.

Another embodiment is to provide a color filter manufactured by using the photosensitive resin film.

### Technical Solution

An embodiment of the present invention provides a photosensitive resin composition including (A) a binder resin; (B) a colorant; (C) a polymerizable compound; (D) an initiator comprising a photopolymerization initiator and a thermal polymerization initiator; and (E) a solvent, wherein the thermal polymerization initiator has a half-life of 50 or less (t½ = 10 h), and the thermal polymerization initiator is included in an amount equal to or greater than that of the photopolymerization initiator.

The thermal polymerization initiator may be a peroxide-based compound.

The thermal polymerization initiator may include a peroxydicarbonate-based compound, a peroxyester-based compound, or a combination thereof.

The thermal polymerization initiator may be included in an amount of 1 wt% to 2 wt% based on the total amount of the photosensitive resin composition.

The colorant may include a pigment, a dye, or a combination thereof.

The dye may include a phthalocyanine-based compound.

The colorant may include a pigment and a dye, and the dye may be included in an amount greater than that of the pigment.

The binder resin may include an acryl-based binder resin, a cardo-based binder resin, or a combination thereof.

The acryl-based binder resin and cardo-based binder resin may be included in a weight ratio of 1:1.

The polymerizable compound may include a photopolymerizable compound and a thermally polymerizable compound.

The photopolymerizable compound and the thermally polymerizable compound may be included in a weight ratio of 1:1.

The photosensitive resin composition may include 1 wt% to 10 wt% of the (A) binder resin; 50 wt% to 80 wt% of the (B) colorant; 1 wt% to 10 wt% of the (C) polymerizable compound; 1.1 wt% to 5 wt% of the (D) initiator; and a balance amount of the (E) solvent.

The photosensitive resin composition may further include at least one additive selected from malonic acid; 3-amino-1,2-propanediol; a coupling agent; a leveling agent; and a surfactant.

Another embodiment provides a photosensitive resin film manufactured using the photosensitive resin composition.

Another embodiment provides a color filter including the photosensitive resin film.

Other embodiments of the present invention are included in the following detailed description.

### Advantageous Effects

The photosensitive resin composition according to the embodiment has a high curing degree not only at high temperatures but also at low temperatures, such as 80° C. to 100° C., thereby providing a color filter having excellent heat resistance and chemical resistance.

### DESCRIPTION OF THE DRAWINGS

FIG. 1 is an optical microscopic photograph after immersing a pattern prepared using the photosensitive resin composition according to Example 1 in a PGMEA solution at room temperature (15° C. to 25° C. for 30 minutes).

### MODE FOR INVENTION

Hereinafter, embodiments of the present invention are described in detail. However, these embodiments are exemplary, the present invention is not limited thereto and the present invention is defined by the scope of claims.

As used herein, when specific definition is not otherwise provided, the term “substituted” may refer to substation with a halogen atom (F, Cl, Br, I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, ester group, an ether group, a carboxyl group or a salt thereof, a sulfonic acid group or a salt thereof, a phosphoric acid or a salt thereof, a C1 to C20 alkyl group, C2 to C20 alkenyl group, a C2 to C20 alkynyl group, a C6 to C30 aryl group, C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof, instead of at least one hydrogen of a compound.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C6 to C20 arylalkyl group, “alkylene group” refers to a C1 to C20 alkylene group, “arylene group” refers to a C6 to C20 arylene group, “alkylarylene group” refers to a C6 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “hetero” refers to inclusion of at least one heteroatom of N, O, S, and P, in the chemical formula. For example, “heterocycloalkyl group,” “heterocycloalkenyl group,” “heterocycloalkynyl group” and “heterocycloalkylene group” refer to a cycloalkyl, cycloalkenyl, cycloalkynyl and cycloalkylene cyclic compound including at least one heteroatom of N, O, S, or P.

As used herein, when specific definition is not otherwise provided, “(meth)acrylate” refers to both “acrylate” and “methacrylate,” and “(meth)acrylic acid” refers to both “acrylic acid” and “methacrylic acid.”

As used herein, when specific definition is not otherwise provided, the term “combination” refers to mixing or copolymerization. Also, “copolymerization” refers to block copolymerization or random copolymerization, and “copolymer” refers to a block copolymer or a random copolymer.

In the chemical formulas of the present specification, when a definition is not otherwise provided, hydrogen is bonded at the position when a chemical bond is not drawn where supposed to be given.

In the present specification, the cardo-based resin refers to a resin including at least one functional group selected from Chemical Formulas 1-1 to Chemical Formula 1-11 in the backbone.

Also, in the present specification, when a definition is not otherwise provided, “ * “refers to a linking part between the same or different atoms, or chemical formulas.

An embodiment provides a photosensitive resin composition including (A) a binder resin; (B) a colorant; (C) a polymerizable compound; (D) an initiator including a photopolymerization initiator and a thermal polymerization initiator; and (E) a solvent, wherein the thermal polymerization initiator has a half-life of 50 or less (t½ = 10 h), and the thermal polymerization initiator is included in an amount equal to or greater than that of the photopolymerization initiator.

As described above, a color filter using the photosensitive resin composition may be formed by coating three or more colors on a transparent substrate mainly in a dyeing method, an electrodeposition method, a printing method, a pigment dispersion method, and the like, and in recent years, as pigment dispersion technology has been improved, the pigment dispersion method which secures excellent color reproducibility and durability against heat, light, and humidity is mainly used. A color filter using this pigment dispersion method is to realize high luminance and a high contrast ratio by using pigment refinement, surface treatment, and the like, or in recent years, development of a high performance color filter by applying a dye is in progress. In addition, in order to make a display flexible, various types of substrates are applied thereto, and in particular, in order to form a color filter in an organic plastic substrate, development of a photosensitive resin composition for a color filter that can satisfy the limited process conditions is required.

In particular, when a plastic substrate is used for a display, since thermally deformed during the high-temperature process, a low-temperature process is required, and in addition, since an organic light emitting diode (OLED) requires only the low-temperature process due to material properties, demand for a low-temperature curable resin composition is increasing. However, the low-temperature curable resin composition is not sufficiently cured during the low-temperature curing and has a problem of weak heat resistance and chemical resistance. In an embodiment, a thermal polymerization initiator having a half-life (t½ = 10 h) of less than or equal to 50 is used with a photopolymerization initiator, wherein a content of the thermal polymerization initiator is larger than that of the photopolymerization initiator to increase a curing degree at a low temperature, providing a photosensitive resin composition for a color filter having high resolution, high heat resistance, and high chemical resistance even in the low-temperature curing process.

Hereinafter, each component is described in detail.

### (D) Initiator

As for an initiator constituting the conventional photosensitive resin composition, the photopolymerization initiator is mostly used alone, and accordingly, this photosensitive resin composition exhibits excellent high-temperature curing properties but very inferior low-temperature curing properties. Accordingly, attempts to use the thermal polymerization initiator instead of the photopolymerization initiator have been made but result in only slightly improving low-temperature curing properties.

According to an embodiment, the thermal polymerization initiator and the photopolymerization initiator are mixed, and simultaneously, the content of the thermal polymerization initiator is the same as or larger than that of the photopolymerization to well promote curing at both high and low temperatures, and in particular, as for the thermal polymerization initiator, a compound having a half-life (t½=10 h) of less than or equal to 50, for example, 40 to 50 may be used to maximize the low-temperature curing properties. When the content of the thermal polymerization initiator is smaller than that of the photopolymerization initiator, the low-temperature curing properties may be deteriorated, and even when the thermal polymerization initiator having a half-life (t½=10 h) of greater than 50 is used, the low-temperature curing properties are deteriorated.

Meanwhile, the half-life (t½=10 h) of each thermal polymerization initiator is shown in Table 1.

TABLE 1

| | Half-life (t½=10 h) |
|---|---|
| PeroylTCP (Peroxydicarbonate) | 40.8 |
| PerbutylND (Peroxyester) | 46.4 |
| Peroyl-L (Lauroyl Peroxide) | 61.6 |
| ChemexBO (tert-butyl peroxy-2-ethylhexanoate) | 72.1 |
| BPO (Benzoyl peroxide) | 73.6 |
| PerbutylIB (tert-butyl peroxy isobutyrate) | 77.3 |
| PerhexaC (1,1-Bis(t-butylperoxy cyclohexane) | 90.7 |

For example, the thermal polymerization initiator may be a peroxide-based compound. In this case, low-temperature curing characteristics may be further improved than when other series of compounds are used as the thermal polymerization initiator.

For example, the thermal polymerization initiator may include a peroxydicarbonate-based compound, a peroxyester-based compound, or a combination thereof.

For example, the thermal polymerization initiator may be included in an amount of 1 wt% to 2 wt% based on the total amount of the photosensitive resin composition. When the thermal polymerization initiator is included within the above range, room temperature stability may be improved. That is, when the thermal polymerization initiator is included in an amount of less than 1 wt% relative to the total amount of the photosensitive resin composition, its content is too small, and it may be difficult to contribute to maximization of low-temperature curing characteristics, while when the thermal polymerization initiator is included in an amount of more than 2 wt% relative to the total amount of the photosensitive resin composition, room temperature stability may be lowered and gelation may occur, which may be undesirable.

The photopolymerization initiator may be a generally-used photopolymerization initiator in a photosensitive resin composition, and may be for example an acetophenone-based compound, a benzophenone-based compound, a thioxanthone-based compound, a benzoin-based compound, a triazine-based compound, an oxime-based compound, or a combination thereof.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be an O-acyloxime-based compound, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

The photopolymerization initiator may include a carbazole-based compound, a diketone-based compound, a sulfonium borate-based compound, a diazo-based compound, an imidazole-based compound, a biimidazole-based compound, a fluorene-based compound, and the like.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of 0.1 wt% to 5 wt%, for example 0.1 wt% to 3 wt% based on the total amount of the photosensitive resin composition. When the photopolymerization initiator is included within the ranges, sufficient curing occurs during exposure in a pattern-forming process, excellent reliability may be realized, heat resistance, light resistance, and chemical resistance of patterns, resolution and close-contacting properties may be improved, and decrease of transmittance due to a non-reaction initiator may be prevented.

The initiator (thermal polymerization initiator and photopolymerization initiator) in the photosensitive resin composition according to an embodiment may be included in an amount of 1.1 wt% to 5 wt% based on the total amount of the photosensitive resin composition, but in this case when the content of the thermal polymerization initiator is equal to or greater than the content of the photopolymerization initiator, low-temperature curing characteristics may be greatly improved.

### (A) Binder Resin

The binder resin may include an acryl-based binder resin, a cardo-based binder resin, or a combination thereof.

The acryl-based binder resin is a copolymer of a first ethylenic unsaturated monomer and a second ethylenic unsaturated monomer that is copolymerizable with the first ethylenic unsaturated monomer, and a resin including at least one acryl-based repeating unit.

The first ethylenic unsaturated monomer is an ethylenic unsaturated monomer including at least one carboxyl group and examples of the monomer include acrylic acid, methacrylic acid, maleic acid, itaconic acid, fumaric acid, or a combination thereof.

The first ethylenic unsaturated monomer may be included in an amount of 5 wt% to 50 wt%, for example 10 wt% to 40 wt% based on the total amount of the acryl-based binder resin.

Examples of the second ethylenic unsaturated monomer may include an aromatic vinyl compound such as styrene, α-methylstyrene, vinyltoluene, vinylbenzylmethylether, and the like; an unsaturated carboxylic acid ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, and the like; an unsaturated carboxylic acid amino alkyl ester compound such as 2-aminoethyl(meth)acrylate, 2-dimethylaminoethyl(meth)acrylate, and the like; a carboxylic acid vinyl ester compound such as vinyl acetate, vinyl benzoate, and the like; an unsaturated carboxylic acid glycidyl ester compound such as glycidyl(meth)acrylate and the like; a vinyl cyanide compound such as (meth)acrylonitrile and the like; an unsaturated amide compound such as (meth)acrylamide and the like; and the like, and may be used alone or as a mixture of two or more.

Specific examples of the acryl-based binder resin may be a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto, and may be used alone or as a mixture of two or more.

A weight average molecular weight of the acryl-based binder resin may be 3,000 g/mol to 150,000 g/mol, for example 5,000 g/mol to 50,000 g/mol, for example 20,000 g/mol to 30,000 g/mol. When the acryl-based binder resin has a weight average molecular weight within the range, the photosensitive resin composition may have excellent physical and chemical properties and an appropriate viscosity, and show excellent close-contacting properties to a substrate during manufacture of a color filter.

For example, the cardo-based binder resin may be represented by Chemical Formula 1.

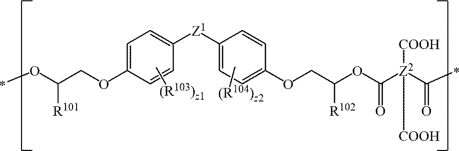

In Chemical Formula 1,
R¹⁰¹ and R¹⁰² are each independently a hydrogen atom or a substituted or unsubstituted (meth)acryloyloxy alkyl group,
R¹⁰³ and R¹⁰⁴ are each independently a hydrogen atom, a halogen atom or a substituted or unsubstituted C1 to C20 alkyl group, and
Z¹ is a single bond, O, CO, SO₂, CR¹⁰⁷R¹⁰⁸, SiR¹⁰⁹R¹¹⁰ (wherein, R¹⁰⁷ to R¹¹⁰ are each independently a hydrogen atom or a substituted or unsubstituted C1 to C20 alkyl group) or one of linking groups represented by Chemical Formulas 1-1 to 1-11,

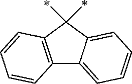

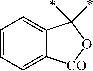

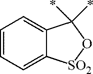

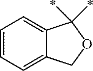

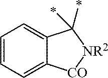

(wherein, in Chemical Formula 1-5, R^{z} is a hydrogen atom, an ethyl group, C₂H₄Cl, C₂H₄OH, CH₂CH═CH₂, or a phenyl group)

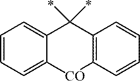

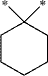

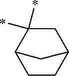

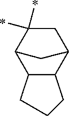

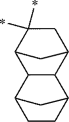

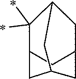

Z² is an acid anhydride moiety or an acid dianhydride moiety, and
z1 and z2 are each independently an integer of 0 to 4.

The cardo-based resin may have a weight average molecular weight of 500 g/mol to 50,000 g/mol, for example, 1,000 g/mol to 30,000 g/mol. When the weight average molecular weight of the cardo-based resin is within the above range, a pattern may be formed without a residue when the light blocking layer is manufactured, there is no loss of film thickness during development, and a good pattern may be obtained.

The cardo-based resin may include a functional group represented by Chemical Formula 2 at at least one of both terminal ends.

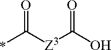

In Chemical Formula 2, Z³ may be represented by Chemical Formulas 2-1 to 2-7.

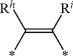

(wherein, in Chemical Formula 2-1, R^{h} and Rⁱ are each independently a hydrogen atom, a substituted or unsubstituted C1 to C20 alkyl group, an ester group, or an ether group.)

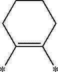

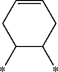

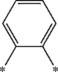

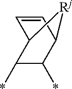

(wherein, in Chemical Formula 2-5, R^{j} is O, S, NH, a substituted or unsubstituted C1 to C20 alkylene group, a C1 to C20 alkylamine group, or a C2 to C20 alkenylamine group.)

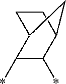

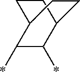

The cardo-based resin may be prepared by mixing, for example, at least two of a fluorine-containing compound such as 9,9-bis(4-oxiranylmethoxyphenyl)fluorene, and the like; an anhydride compound such as benzenetetracarboxylic dianhydride, naphthalenetetracarboxylic dianhydride, biphenyltetracarboxylic dianhydride, benzophenonetetracarboxylic dianhydride, pyromellitic dianhydride, cyclobutanetetracarboxylic dianhydride, perylenetetracarboxylic dianhydride, tetrahydrofurantetracarboxylic dianhydride, tetrahydrophthalic anhydride, and the like; a glycol compound such as ethylene glycol, propylene glycol, polyethylene glycol, and the like; an alcohol compound such as methanol, ethanol, propanol, n-butanol, cyclohexanol, benzylalcohol, and the like; a solvent-series compound such as propylene glycol methylethylacetate, N-methylpyrrolidone, and the like; a phosphorus compound such as triphenylphosphine, and the like; and an amine or ammonium salt compound such as tetramethylammonium chloride, tetraethylammonium bromide, benzyldiethylamine, triethylamine, tributylamine, benzyltriethylammonium chloride, and the like.

When the binder resin includes both the acryl-based binder resin and cardo-based binder resin, the acryl-based binder resin and cardo-based binder resin may be included in a weight ratio of 1:1. in this case, the photosensitive resin composition has excellent developability, and has excellent sensitivity during photocuring, so that fine pattern formation may be improved.

The binder resin may be included in an amount of 1 wt% to 10 wt%, for example 3 wt% to 8 wt% based on the total amount of the photosensitive resin composition. When the binder resin is included within the range, the composition may have an excellent developability and improved crosslinking, and thus has excellent surface flatness when manufactured into a color filter.

### (B) Colorant

The colorant in the photosensitive resin composition according to an embodiment may include a pigment, a dye, or a combination thereof.

For example, the dye may include a phthalocyanine-based compound.

When the phthalocyanine-based compound is used as a dye, a high color can be expressed even in a small amount, so that a display device having excellent color characteristics such as luminance may be manufactured.

For example, when the phthalocyanine-based compound is used as a dye, when it is used with a pigment dispersion, such as a yellow or green pigment dispersion, high color coordinates with improved reliability including coloring properties, luminance characteristics and chemical resistance may be implemented. For example, the colorant in the photosensitive resin composition according to the embodiment includes a pigment (pigment dispersion) and a dye (phthalocyanine-based compound), and the dye may be included in an amount greater than that of the pigment. When the dye including the phthalocyanine-based compound is included in a content range greater than that of the pigment (pigment dispersion), reliability of the photosensitive resin composition may be improved.

For example, the colorant may be included in an amount of 50 wt% to 80 wt%, for example 60 wt% to 75 wt%, based on the total amount of the photosensitive resin composition. When the colorant is included in the content range, improved dissolution resistance can be secured when implementing high color coordinates.

For example, the pigment may include a green pigment, a yellow pigment, or a combination thereof.

The green pigment may include green pigment C.I. pigment green 7, C.I. pigment green 36, C.I. pigment green 37, C.I. pigment green 58, C.I. pigment green 59, C.I. pigment green 62 or a combination thereof.

The yellow pigment may include C.I. pigment yellow 11, C.I. pigment yellow 24, C.I. pigment yellow 31, C.I. pigment yellow 53, C.I. pigment yellow 83, C.I. pigment yellow 93, C.I. pigment yellow 99, C.I. pigment yellow 108, C.I. pigment yellow 109, C.I. pigment yellow 110, C.I. pigment yellow 138, C.I. pigment yellow 139, C.I. pigment yellow 147, C.I. pigment yellow 150, C.I. pigment yellow 151, C.I. pigment yellow 154, C.I. pigment yellow 155, C.I. pigment yellow 167, C.I. pigment yellow 180, C.I. pigment yellow 185, C.I. pigment yellow 199, C.I. pigment yellow 215, C.I. pigment yellow 231, or a combination thereof.

The green pigment and the yellow pigment may be used with a dispersant in in order to disperse pigments. Specifically, the pigment may be pretreated with the dispersant on the surface or added with the pigment to prepare the composition.

The dispersant may be a non-ionic dispersant, an anionic dispersant, a cationic dispersant, and the like. Specific examples of the dispersant may be polyalkylene glycol and esters thereof, polyoxyalkylene, polyhydric alcohol ester alkylene oxide addition product, an alcohol alkylene oxide addition product, sulfonate ester, sulfonate salt, a carboxylate ester, a carboxylate salt, an alkylamide alkylene oxide addition product, alkyl amine, and the like, and may be used alone or as a mixture of two or more.

Commercially available examples of the dispersant may include DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001, and the like made by BYK Co., Ltd.; EFKA-47, EFKA-47EA, EFKA-48, EFKA-49, EFKA-100, EFKA-400, EFKA-450, and the like made by EFKA Chemicals Co.; Solsperse 5000, Solsperse 12000, Solsperse 13240, Solsperse 13940, Solsperse 17000, Solsperse 20000, Solsperse 24000GR, Solsperse 27000, Solsperse 28000, and the like made by Zeneka Co.; or PB711, or PB821 made by Ajinomoto Inc.

The dispersant may be included in an amount of 0.1 wt% to 15 wt% based on the total amount of photosensitive resin composition. When the dispersant is included within the range, the composition has excellent stability, developability, and patternability due to improved dispersion properties during manufacture of a black column spacer.

The pigment may be pre-treated using a water-soluble inorganic salt and a wetting agent. When the pigment is pre-treated, an average particle diameter of the pigment may become finer.

The pre-treatment may be performed by kneading the pigment with a water-soluble inorganic salt and a wetting agent and then, filtering and washing the knead pigment.

The kneading may be performed at a temperature of 40° C. to 100° C., and the filtering and washing may be performed by filtering the pigment after washing away an inorganic salt with water and the like.

Examples of the water-soluble inorganic salt may be sodium chloride, potassium chloride, and the like, but are not limited thereto. The wetting agent may make the pigment to be uniformly mixed with the water-soluble inorganic salt uniformly and be pulverized. Examples of the wetting agent include alkylene glycol monoalkyl ethers such as ethylene glycol monoethylether, propylene glycol monomethylether, diethylene glycol monomethylether, and the like, and alcohols such as ethanol, isopropanol, butanol, hexanol, cyclohexanol, ethylene glycol, diethylene glycol, polyethylene glycol, glycerine polyethylene glycol, and the like, and these may be used alone or as a mixture of two or more.

The pigment after the kneading may have an average particle diameter ranging from 5 nm to 200 nm, for example 5 nm to 150 nm. When the pigment has an average particle diameter within the ranges, stability of pigment dispersion may be improved and pixel resolution may not be deteriorated.

A solvent for forming the pigment dispersion may be ethylene glycol acetate, ethylcellosolve, propylene glycolmethylether acetate, ethyllactate, polyethylene glycol, cyclohexanone, propylene glycol methylether, and the like.

Specifically, the pigment may be used in a form of pigment dispersion including the dispersing agent and a solvent which will be described later, and the pigment dispersion may include a solid pigment, a dispersing agent, and a solvent. The solid pigment may be included in an amount of 5 wt% to 30 wt%, for example 8 wt% to 20 wt% based on the total amount of the pigment dispersion.

### (C) Polymerizable Compound

The polymerizable compound may include a photopolymerizable compound and a thermally polymerizable compound.

The photopolymerizable compound may be mono-functional or multi-functional ester of (meth)acrylic acid including at least one ethylenic unsaturated double bond.

The photopolymerizable compound has the ethylenic unsaturated double bond and thus, may cause sufficient polymerization during exposure in a pattern-forming process and form a pattern having excellent heat resistance, light resistance, and chemical resistance.

Specific examples of the photopolymerizable compound may be ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Commercially available examples of the photopolymerizable compound are as follows. The mono-functional (meth)acrylic acid ester may include Aronix M-101^{®}, M-111^{®}, M-114^{®} (Toagosei Chemistry Industry Co., Ltd.); KAYARAD TC-110S^{®}, TC-120S^{®} (Nippon Kayaku Co., Ltd.); V-158^{®}, V-2311^{®} (Osaka Organic Chemical Ind., Ltd.), and the like. Examples of a difunctional (meth)acrylic acid ester may include Aronix M-210^{®}, M-240^{®}, M-6200^{®} (Toagosei Chemistry Industry Co., Ltd.), KAYARAD HDDA^{®}, HX-220^{®}, R-604^{®} (Nippon Kayaku Co., Ltd.), V-260^{®}, V-312^{®}, V-335 HP^{®} (Osaka Organic Chemical Ind., Ltd.), and the like. Examples of a tri-functional (meth)acrylic acid ester may include Aronix M-309^{®}, M-400^{®}, M-405^{®}, M-450^{®}, M-710^{®}, M-8030^{®}, M-8060^{®} (Toagosei Chemistry Industry Co., Ltd.), KAYARAD TMPTA^{®}, DPCA-20^{®}, DPCA-30^{®}, DPCA-60^{®}, DPCA-120^{®} (Nippon Kayaku Co., Ltd.), V-295^{®}, V-300^{®}, V-360^{®}, V-GPT^{®}, V-3PA^{®}, V-400^{®} (Osaka Yuki Kayaku Kogyo Co. Ltd.), and the like. These may be used alone or as a mixture of two or more.

The photopolymerizable compound may be treated with acid anhydride to improve developability.

The photopolymerizable compound may be included in an amount of 0.5 wt% to 5 wt%, for example 1 wt% to 4 wt% based on the total amount of the photosensitive resin composition. When the photopolymerizable compound is included within the range, the photopolymerizable compound is sufficiently cured during exposure in a pattern-forming process and has excellent reliability, and developability for alkali developing solution may be improved.

The thermally polymerizable compound may include a (meth)acrylate-based compound, an oxetane-based compound, a thiol group-containing compound, or a combination thereof.

The thermally polymerizable compound may include an oxetanyl group, a thiol group, a (meth)acrylate group, and the like as a functional group to increase a curing degree during photocuring and thermal curing.

Specifically, when the oxetane-based compound, the (meth)acrylate-based compound, or the thiol group-containing compound is used as a thermally polymerizable compound and mixed with the aforementioned photopolymerizable compound, reactivity of the thermal polymerization initiator, more specifically, the peroxide-based compound may be greatly improved. In addition, the odor problem generated during the color filter process may be improved.

In addition, when the (meth)acrylate-based compound is used as a thermally polymerizable compound, sufficient polymerization occurs during exposure in the pattern formation process due to the ethylenically unsaturated double bond in the (meth)acrylate-based compound, and a pattern having excellent heat resistance, light resistance and chemical resistance may be formed.

The polymerizable compound may be used by treating it with an acid anhydride in order to provide more excellent developability.

The photopolymerizable compound and the thermally polymerizable compound may be included in a weight ratio of 1:1. In this case, curing occurs sufficiently during exposure in the pattern forming process, and thus reliability is improved.

The thermally polymerizable compound may be included in an amount of 0.5 wt% to 5 wt%, for example 1 wt% to 4 wt%, based on the total amount of the photosensitive resin composition. When the thermally polymerizable monomer is included within the above range, curing occurs sufficiently during exposure in the pattern forming process, and thus reliability is improved, and reliability may be further improved during low-temperature curing.

The photosensitive resin composition according to an embodiment may include the polymerizable compound in an amount of 1 wt% to 10 wt%, for example 3 wt% to 8 wt%, based on the total amount of the photosensitive resin composition. In this case, the pattern has improved heat resistance, light resistance, chemical resistance, resolution, and close contacting properties.

### (E) Solvent

The solvent may be a material that does not react but has compatibility with the binder resin, colorant, polymerizable compound, and initiator according to an embodiment.

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethyl ether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. Additionally, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like may be also used.

Considering miscibility and reactivity, ketones such as cyclohexanone, and the like; glycol ethers such as ethylene glycol monoethylether, and the like; ethylene glycol alkylether acetates such as ethyl cellosolve acetate, and the like; esters such as 2-hydroxy ethyl propionate, and the like; carbitols such as diethylene glycol monomethylether, and the like; propylene glycol alkylether acetates such as propylene glycol monomethylether acetate, propylene glycol propylether acetate and the like, ketones such as cyclohexanone may be desirably used.

The solvent may be used in a balance amount, for example 5 wt% to 30 wt% based on the total amount of the photosensitive resin composition. When the solvent is included within the above range, a coating film having excellent coating properties of the photosensitive resin composition and excellent flatness may be obtained.

### (F) Other Additives

The photosensitive resin composition may further include at least one additive selected from malonic acid; 3-amino-1,2-propanediol; a coupling agent; a leveling agent; and a surfactant in order to prevent stains or spots during the coating, to improve leveling performance, or to prevent residue generation due to non-development.

The additive may be adjusted according to desired properties.

The coupling agent may be a silane-based coupling agent, and examples of the silane-based coupling agent include trimethoxysilyl benzoic acid, γ-methacryl oxypropyl trimethoxysilane, vinyl triacetoxysilane, vinyl trimethoxysilane, γ-Isocyanate propyl triethoxysilane, γ-glycidoxy propyl trimethoxysilane, β-epoxycyclohexyl) ethyl trimethoxysilane, etc., and these may be used alone or in mixture of 2 or more types.

Specifically, the silane-based coupling agent may be used in an amount of 0.01 part by weight to 1 part by weight based on 100 parts by weight of the photosensitive resin composition.

In addition, the photosensitive resin composition for a color filter may further include a surfactant, such as a fluorine-based surfactant, if necessary.

Examples of the fluorine-based surfactant include F-482, F-484, F-478, and the like of DIC Co., Ltd., but is not limited thereto.

The surfactant may be desirably included in an amount of 0.01 wt% to 5 wt%, more desirably 0.01 wt% to 2 wt%, based on the total amount of the photosensitive resin composition. If it is out of the above range, foreign particles may be generated after development.

Furthermore, the photosensitive resin composition may include other additives such as an antioxidant, a stabilizer, and the like in a predetermined amount unless they deteriorate properties of the photosensitive resin composition.

According to another embodiment, a photosensitive resin film manufactured by using the photosensitive resin composition according to the embodiment is provided.

According to another embodiment, a color filter manufactured using the aforementioned photosensitive resin composition is provided.

A method of manufacturing the color filter is as follows.

The above photosensitive resin composition is coated to form a 0.5 µm to 10 µm-thick photosensitive resin composition layer on a glass substrate in an appropriate method such as spin coating, roller coating, spray coating, and the like.

Subsequently, the substrate having the photosensitive resin composition layer is radiated by light to form a pattern required for a color filter. As a light source used for irradiation, UV, electron beam, or X-ray may be used, and for example, UV in a region of 190 nm to 450 nm, specifically 200 nm to 400 nm may be irradiated. In the irradiation process, a photoresist mask may be further used. After performing the irradiation process in this way, the photosensitive resin composition layer irradiated with the light source is treated with a developing solution. At this time, the unexposed portion of the photosensitive resin composition layer is dissolved to form a pattern necessary for the color filter. By repeating this process according to the number of required colors, a color filter having a desired pattern may be obtained. In addition, when an image pattern obtained by development in the above process is heated again or cured by irradiation with actinic rays, crack resistance and solvent resistance may be improved.

Hereinafter, the present invention is illustrated in more detail with reference to examples, but these examples, however, are not in any sense to be interpreted as limiting the scope of the invention.

### Synthesis of Photosensitive Resin Composition

### Examples 1 to 4 and Comparative Examples 1 to 6

Photosensitive resin compositions according to Examples 1 to 4 and Comparative Examples 1 to 6 were prepared to include the following components in each composition shown in Table 1.

Specifically, an initiator was dissolved in a solvent and then, stirred at room temperature for 2 hours, and a binder resin and a photopolymerizable compound were added thereto and then, stirred at room temperature for 2 hours.

Then, a colorant and other additives were added thereto and then, stirred at room temperature. Subsequently, a product obtained therefrom was three times filtered to remove impurities, preparing the photosensitive resin compositions.

TABLE 2

(unit: wt%)

| | | Ex. 1 | Ex. 2 | Ex. 3 | Ex. 4 | Comp . Ex. 1 | Comp . Ex. 2 | Comp . Ex. 3 | Comp . Ex. 4 | Comp . Ex. 5 | Comp . Ex. 6 |
|---|---|---|---|---|---|---|---|---|---|---|---|
| (A) binder resin | A-1 | 3 | 3 | 3 | 3 | 3 | 3 | 3 | 3 | 3 | 3 |
| | A-2 | 3 | 3 | 3 | 3 | 3 | 3 | 3 | 3 | 3 | 3 |
| (B) colorant | B-1 | 48 | 48 | 48 | 48 | 48 | 48 | 48 | 48 | 48 | 48 |
| | B-2 | 22.5 | 22.5 | 22.5 | 22.5 | 22.5 | 22.5 | 22.5 | 22.5 | 22.5 | 22.5 |
| | B-3 | 3.5 | 3.5 | 3.5 | 3.5 | 3.5 | 3.5 | 3.5 | 3.5 | 3.5 | 3.5 |
| (C) polymeri | C-1 | 2.5 | 2.5 | 2.5 | 2.5 | 2.5 | 2.5 | 2.5 | 2.5 | 2.5 | 2.5 |
| | C-2 | 2.5 | 2.5 | 2.5 | 2.5 | 2.5 | 2.5 | 2.5 | 2.5 | 2.5 | 2.5 |
| zable compoun d | | | | | | | | | | | |
| (D-1) photopol ymerizati on initiator | D-1-1 | 1 | 1 | 0.7 | 0.7 | 1 | 1 | 1 | 1 | 1 | 1 |
| | D-1-2 | 0.3 | 0.3 | 0.3 | 0.3 | 0.3 | 0.3 | 0.3 | 0.3 | 0.3 | 0.3 |
| (D-2) thermal polymeri zation initiator | D-2-1 | 2 | - | 1 | - | 1 | 3 | - | - | - | - |
| | D-2-2 | - | 2 | - | 1 | - | - | - | - | - | - |
| | D-2-3 | - | - | - | - | - | - | 2 | - | - | - |
| | D-2-4 | - | - | - | - | - | - | - | 2 | - | - |
| | D-2-5 | - | - | - | - | - | - | - | - | 2 | - |
| | D-2-6 | - | - | - | - | - | - | - | - | - | 2 |
| (E) solvent | | 8.5 | 8.5 | 9.8 | 9.8 | 9.5 | 7.5 | 8.5 | 8.5 | 8.5 | 8.5 |
| (F) other additive | F-1 | 0.2 | 0.2 | 0.2 | 0.2 | 0.2 | 0.2 | 0.2 | 0.2 | 0.2 | 0.2 |
| | F-2 | 3 | 3 | 3 | 3 | 3 | 3 | 3 | 3 | 3 | 3 |

(A) Binder resin
   (A-1) Acryl-based binder resin (RY-25, Showa Denko)
   (A-2) Cardo-based binder resin (KBR101, Gyeongin)
(B) Colorant
   (B-1) Phthalocyanine dye (GD17, Kyung-In Synthetic Corporation)
   (B-2) Yellow pigment dispersion (Y231, Toyo Ink)
   (B-3) Yellow pigment dispersion (Y139, Toyo Ink)
(C) Polymerizable compound
   (C-1) M300 (Trimethylolpropane triacrylate, Miwon Specialty)
   (C-2) V1000 (represented by Chemical Formula E, Osaka Chemical)

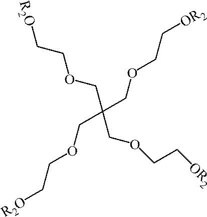

(In Chemical Formula E, R₁ is represented by Chemical Formula E-1,

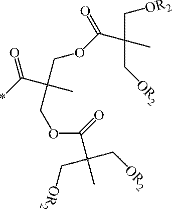

wherein, in Chemical Formula E-1,
R₂ is hydrogen or *—C(═O)—CR═CH₂, and
R₃ is *—C(═O)—CR═CH₂,
wherein R is hydrogen atom or a C1 to C10 alkyl group.)
(D-1) Photopolymerization initiator
   (D-1-1) SPI-05 (Samyang)
   (D-1-2) SPI-03 (Samyang)
(D-2) Thermal polymerization initiator
   (D-2-1) PeroylTCP (Peroxydicarbonate) (Dongsung Hi-Chem)
   (D-2-2) PerbutylND (Peroxyester) (Dongsung Hi-Chem)
   (D-2-3) Peroyl-L (Lauroyl Peroxide) (Dongsung Hi-Chem)
   (D-2-4) ChemexBO (tert-butyl peroxy-2-ethylhexanoate) (Dongsung Hi-Chem)
   (D-2-5) PerbutylIB (tert-butyl peroxy isobutyrate) (Dongsung Hi-Chem)
   (D-2-6) PerhexaC (1,1-Bis(t-butylperoxy cyclohexane) (Dongsung Hi-Chem)
(E) Solvent
   Propylene glycolmonomethyl ether acetate (Sigma-Aldrich Corporation)
(F) Other additives
   (F-1) Leveling agent (F-554, DIC)
   (F-2) Silane-based coupling agent (KBM503, Shin-Etsu)

### Evaluation 1: Chemical Resistance

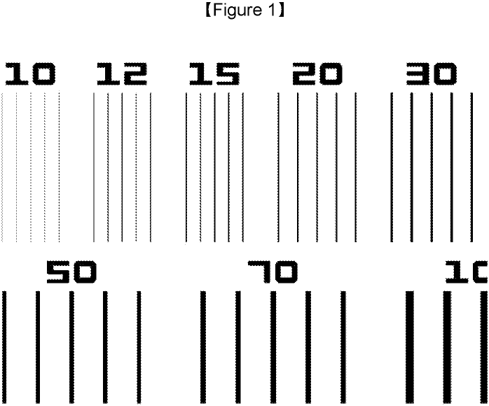

The photosensitive resin composition according to Examples 1 to 4 and Comparative Examples 1 to 6 were respectively coated to be 3 µm thick on a transparent decreased glass substrate (bare glass) by using a spin-coater (K-Spin8, KDNS) and then, dried on an 80° C. hot plate for 120 seconds, obtaining dry films. The films were exposed to light with output (power) of 50 mJ/cm² by using a lamp with a main wavelength of 365 nm and then, baked in an 85° C. forced convection oven for 60 minutes, preparing specimens. The specimens were cut into a size of 2 cm×2 cm and then, dipped in a PGMEA solution for 30 minutes, and an optical microscope was used to examine whether a remaining pattern was peeled or not. When a patten was not peeled but remained, “Δ” was given, when a pattern was peeled but a little remained, “Δ” was given, and when a pattern was peeled and did not remain, “” was given, and the results are shown in Table 3. In addition, a specimen formed of the photosensitive resin composition of Example 1 was dipped in a PGMEA solution for 30 minutes, and a pattern photograph thereof is given in FIG. 1.

TABLE 3

| | |
|---|---|
| | Chemical resistance |
| Example 1 | O |
| Example 2 | O |
| Example 3 | O |
| Example 4 | O |
| Comparative Example 1 | X |
| Comparative Example 2 | Δ |
| Comparative Example 3 | X |
| Comparative Example 4 | X |
| Comparative Example 5 | X |
| Comparative Example 6 | X |

### Evaluation 2: Storage Stability

The photosensitive resin compositions according to Examples 1 to 4 and Comparative Examples 1 to 6 were allowed to stand at room temperature (25° C.) for 2 weeks, and then, whether or not the solutions were gelated was checked by shaking them. When gelated, ”” was given, when maintained in the liquid state without change, ”” was given, and the results are given in Table 4.

TABLE 4

| | |
|---|---|
| | Storage stability |
| Example 1 | X |
| Example 2 | X |
| Example 3 | X |
| Example 4 | X |
| Comparative Example 1 | X |
| Comparative Example 2 | O |
| Comparative Example 3 | X |
| Comparative Example 4 | X |
| Comparative Example 5 | X |
| Comparative Example 6 | X |

Referring to FIG. 1 and Tables 3 and 4, the photosensitive resin compositions according to an embodiment exhibited very excellent low-temperature curing properties at 85° C., and when the thermal polymerization initiator was included in an excessive amount, storage stability of the photosensitive resin compositions was deteriorated.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photosensitive resin composition, comprising
(A) a binder resin;
(B) a colorant;
(C) a polymerizable compound;
(D) an initiator including a photopolymerization initiator and a thermal polymerization initiator; and
(E) a solvent,
wherein the thermal polymerization initiator has a half-life of 50 or less (t½ = 10 h), and
wherein the thermal polymerization initiator is included in an amount equal to or greater than that of the photopolymerization initiator.

2. The photosensitive resin composition of claim 1, wherein the thermal polymerization initiator is a peroxide-based compound.

3. The photosensitive resin composition of claim 2, wherein the thermal polymerization initiator includes a peroxydicarbonate-based compound, a peroxyester-based compound, or a combination thereof.

4. The photosensitive resin composition of claim 1, wherein the thermal polymerization initiator is included in an amount of 1 wt% to 2 wt% based on a total weight of the photosensitive resin composition.

5. The photosensitive resin composition of claim 1, wherein the colorant includes a pigment, a dye, or a combination thereof.

6. The photosensitive resin composition of claim 5, wherein:
the colorant includes the dye, and
the dye includes a phthalocyanine-based compound.

7. The photosensitive resin composition of claim 6, wherein the colorant further includes the pigment, and the dye is included in an amount greater than that of the pigment.

8. The photosensitive resin composition of claim 1, wherein the binder resin includes an acryl-based binder resin, a cardo-based binder resin, or a combination thereof.

9. The photosensitive resin composition of claim 8, wherein the acryl-based binder resin and cardo-based binder resin are included in a weight ratio of 1:1.

10. The photosensitive resin composition of claim 1, wherein the polymerizable compound includes a photopolymerizable compound and a thermally polymerizable compound.

11. The photosensitive resin composition of claim 10, wherein the photopolymerizable compound and the thermally polymerizable compound are included in a weight ratio of 1:1.

12. The photosensitive resin composition of claim 1, wherein the photosensitive resin composition includes
1 wt% to 10 wt% of the (A) binder resin;
50 wt% to 80 wt% of the (B) colorant;
1 wt% to 10 wt% of the (C) polymerizable compound;
1.1 wt% to 5 wt% of the (D) initiator; and
the (E) solvent,
based on a total weight of the photosensitive resin composition.

13. The photosensitive resin composition of claim 1, wherein the photosensitive resin composition further includes malonic acid; 3-amino-1,2-propanediol; a coupling agent; a leveling agent; or a surfactant.

14. A photosensitive resin film manufactured using the photosensitive resin composition of claim 1.

15. A color filter comprising the photosensitive resin film of claim 14.
